(19) United States
(12) Patent Application Publication
(10) Pub. No.: US 2012/0074484 A1
(43) Pub. Date: Mar. 29, 2012

(54) SEMICONDUCTOR DEVICES AND METHODS OF MANUFACTURING SEMICONDUCTOR DEVICES

(76) Inventors: Jin-Kyu KANG, Seoul (KR); Woon-Kyung LEE, Seongnam-si (KR); Jee-Yong KIM, Hwaseong-si (KR); Jung-Hwan LEE, Seoul (KR)

(21) Appl. No.: 13/223,698

(22) Filed: Sep. 1, 2011

(30) Foreign Application Priority Data
Sep. 27, 2010 (KR) 10-2010-0093183

(51) Int. Cl. H01L 21/336; H01L 29/788

(52) U.S. Cl. 257/316; 438/594; 257/E29.3; 257/E21.422; 257/E21.423

(57) ABSTRACT

A method of manufacturing a semiconductor device including forming a plurality of gate structures spaced apart from each other on a substrate; forming a first insulation layer covering the gate structures, the first insulation layer including a void between the gate structures; removing an upper portion of the first insulation layer to form a first insulation layer pattern on sidewalls of lower portions of the gate structures and on the substrate between the gate structures, the first insulation layer pattern including a first recess thereon; forming a conductive layer on upper portions of the gate structures exposed by the first insulation layer pattern; reacting the conductive layer with the gate structures; and forming a second insulation layer on the upper portions of the gate structures, the second insulation layer including a second recess therebeneath in fluid communication with the first recess.

### CROSS-REFERENCE TO RELATED APPLICATION

Korean Patent Application No. 10-2010-0093183, filed on Sep. 27, 2010, in the Korean Intellectual Property Office, and entitled: “Semiconductor Devices and Methods of manufacturing Semiconductor Devices,” is incorporated by reference herein in its entirety.

### BACKGROUND

Embodiments relate to semiconductor devices and methods of manufacturing semiconductor devices, particularly highly integrated semiconductor devices.

### SUMMARY

Embodiments are directed to semiconductor devices and methods of manufacturing semiconductor devices.

The embodiments may be realized by providing a method of manufacturing a semiconductor device, the method including forming a plurality of gate structures spaced apart from each other on a substrate; forming a first insulation layer covering the gate structures, the first insulation layer including a void between the gate structures; removing an upper portion of the first insulation layer to form a first insulation layer pattern on sidewalls of lower portions of the gate structures and on the substrate between the gate structures, the first insulation layer pattern including a first recess thereon; forming a conductive layer on upper portions of the gate structures exposed by the first insulation layer pattern; reacting the conductive layer with the gate structures; and forming a second insulation layer on the upper portions of the gate structures, the second insulation layer including a second recess therebeneath in fluid communication with the first recess.

The first and second recesses may form an air gap, the first and second recesses defining lower and upper portions of the air gap, respectively.

The first recess may have a width that narrows from a top portion to a bottom portion thereof.

The second recess may have a width that narrows from a bottom portion to a top portion thereof.

The second recess may have a maximum width larger than a maximum width of the first recess.

Each of the gate structures may include a tunnel insulation layer pattern, a floating gate, a dielectric layer pattern, and a control gate sequentially stacked on the substrate, the control gate including doped polysilicon, and the first insulation layer pattern may be formed on the substrate between the gate structures.

The conductive layer may be formed using a metal, and reacting the conductive layer with the gate structures may include forming a metal silicide layer.

The first insulation layer may be formed using at least one selected from the group of middle temperature oxide (MTO), high temperature oxide (HTO), and atomic layer deposition (ALD) oxide.

The second insulation layer may be formed using at least one selected from the group of plasma enhanced oxide (PEOX), MTO, and tetra ethyl ortho silicate (TEOS).

The method may further include at least partially etching sidewalls of the first recess to enlarge the first recess after forming the first insulation layer pattern.

Each of the gate structures may include a tunnel insulation layer pattern, a charge trapping layer pattern, a blocking layer pattern, and a gate electrode sequentially stacked on the substrate, the gate electrode including doped polysilicon, and the first insulation layer pattern may be formed on the substrate between the gate structures.

The embodiments may also be realized by providing a semiconductor device including a plurality of gate structures spaced apart from each other on a substrate; a first insulation layer pattern on sidewalls of lower portions of the gate structures and on a top surface of the substrate between the gate structures, the first insulation layer pattern including a first recess thereon and having a thickness that increases from a top portion to a bottom portion thereof; and a second insulation layer pattern covering upper portions of the gate structures that are not covered by the first insulation layer pattern, the second insulation layer pattern including a second recess therebeneath in fluid communication with the first recess and having a thickness that increases from a bottom portion to a top portion thereof.

The first and second recesses may form an air gap, the first and second recesses defining lower and upper portions of the air gap, respectively.

The second recess may have a maximum width larger than a maximum width of the first recess.

Each of the gate structures may include a tunnel insulation layer pattern, a floating gate, a dielectric layer pattern, and a control gate sequentially stacked on the substrate, the control gate including doped polysilicon, and the first insulation layer pattern may be formed on the substrate between the gate structures.

The embodiments may also be realized by providing a method of manufacturing a semiconductor device, the method including providing a substrate; forming a plurality of gate structures spaced apart from each other on the substrate such that each of the plurality of gate structures includes a tunnel insulation layer pattern, one of a floating gate and charge trapping layer pattern, one of a dielectric layer pattern and a blocking layer pattern, and one of a control gate and a gate electrode sequentially stacked on the substrate; forming a first insulation layer on the plurality of gate structures such that the first insulation layer includes a void between adjacent gate structures; removing an upper portion of the first insulation layer to form a first insulation layer pattern on sidewalls of lower portions of the gate structures and on the substrate between the gate structures such that the first insulation layer pattern includes a first recess therein; forming a conductive layer on upper portions of each control gate or gate electrode; reacting the conductive layer with the upper portions of each control gate or gate electrode to form an upper conductive pattern; and forming a second insulation layer on the gate structures such that the second insulation layer includes a second recess therein and an air gap is formed between adjacent gate structures.

An upper portion of the air gap may be defined by the second recess and a lower portion of the air gap is defined by the first recess.

The second insulation layer may cover the first recess such that the air gap is defined by the second recess.

Reacting the conductive layer with the upper portions of each control gate or gate electrode may include performing a heat treatment.

### BRIEF DESCRIPTION OF THE DRAWINGS

The embodiments will become apparent to those of ordinary skill in the art by describing in detail exemplary embodiments with reference to the attached drawings, in which:

FIG. 1 illustrates a cross-sectional view of a semiconductor device in accordance with an embodiment;

FIGS. 2 to 11 illustrate cross-sectional views of stages in a method of manufacturing a semiconductor device in accordance with an embodiment; and

FIGS. 12 and 13 illustrate cross-sectional views of semiconductor devices in accordance with another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” another element or layer, it can be directly connected or coupled to the other element or layer or intervening elements or layers may be present. In contrast, when an element is referred to as being “ “directly connected to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” other elements or features would then be “upper” elements or features. Thus, the exemplary term “lower” can encompass both an orientation of upper and lower. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

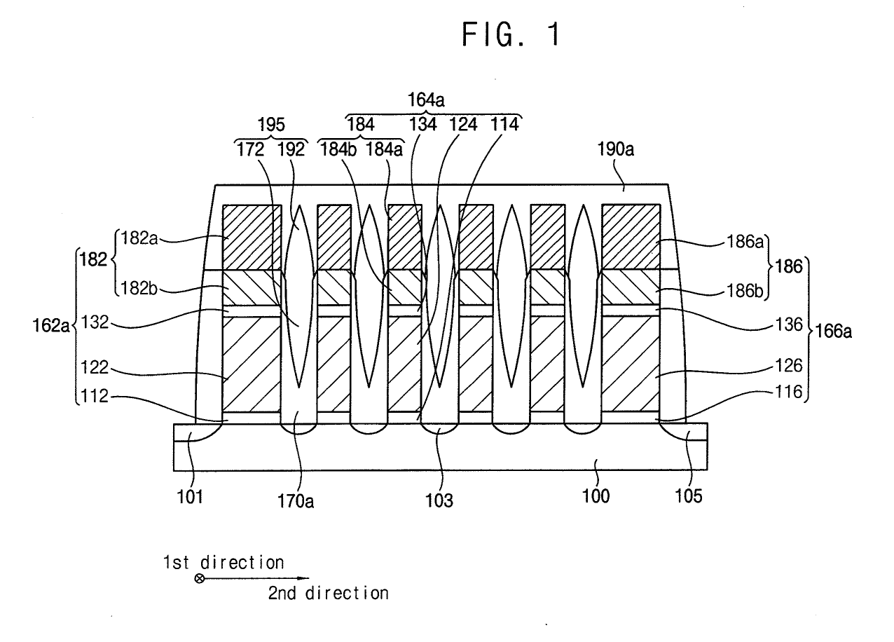

FIG. 1 illustrates a cross-sectional view of a semiconductor device in accordance with an embodiment.

Referring to FIG. 1, the semiconductor device may include first, second, and third gate structures 162a, 164a, and 166a and first and second insulation layer patterns 170a and 190a.

The first, second, and third gate structures 162a, 164a, and 166a may be spaced apart from each other in a second direction on a substrate 100. Each of the first, second, and third gate structures 162a, 164a, and 166a may extend in a first direction substantially perpendicular to the second direction. In an implementation, the first, second, and third gate structures 162a, 164a, and 166a may be disposed in a cell region of the semiconductor device.

In an implementation, the first, second, and third gate structures 162a, 164a, and 166a may respectively include first, second, and third tunnel insulation layer patterns 112, 114, and 116, first, second, and third floating gates 122, 124, and 126, first, second, and third dielectric layer patterns 132, 134, 136, and first, second, and third control gates 182, 184, and 186 sequentially stacked on the substrate 100. The first, second, and third control gates 182, 184, and 186 may include first, second, and third upper conductive patterns 182a, 184a, and 186a, and first, second, and third lower conductive patterns 182b, 184b, and 186b, respectively. In an implementation, the first, second, and third upper conductive patterns 182a, 184a, and 186a may include cobalt silicide.

In another implementation, the first, second, and third gate structures 162a, 164a, and 166a may respectively include first, second, and third tunnel insulation layer patterns 112, 114, and 116, first, second, and third charge trapping layer patterns 122, 124, and 126, first, second, and third blocking layer patterns 132, 134, and 136, and first, second, and third gate electrodes 182, 184, and 186 sequentially stacked on the substrate 100. The first, second, and third gate electrodes 182, 184, and 186 may include first, second, and third upper conductive patterns 182a, 184a, and 186a and first, second, and third lower conductive patterns 182b, 184b, and 186b, respectively.

A first insulation layer pattern 170a may be formed on sidewalls of the first, second, and third gate structures 162a, 164a, and 166a and on the substrate 100 therebetween. For example, the first insulation layer pattern 170a may cover the substrate 100 between the first, second, and third gate structures 162a, 164a, and 166a, and at least sidewalls of the tunnel insulation layer patterns 112, 114, and 116, the floating gates 122, 124, and 126, and the dielectric layer patterns 132, 134, and 136. The first insulation layer pattern 170a may also cover sidewalls of lower portions of the control gates 182, 184, and 186, e.g., the lower conductive patterns 182b, 184b, and 186b.

The first insulation layer pattern 170a may not completely fill spaces between the first, second, and third gate structures 162a, 164a, and 166a. For example, a first recess 172 may be formed on the first insulation layer pattern 170a. In an implementation, the first insulation layer pattern 170a may have a thickness that becomes greater, e.g., that increases, from a top portion to a bottom portion thereof. Accordingly, the first recess 172 may have a width that narrows from a top portion to a bottom portion thereof.

The second insulation layer pattern 190a may cover portions of the first, second, and third gate structures 162a, 164a, and 166a (and may not completely fill the spaces between the first, second, and third gate structures 162a, 164a, and 166a). For example, the second insulation layer pattern 190a may cover portions of the first, second, and third gate structures 162a, 164a, and 166a that are not covered by the first insulation layer pattern 170a (e.g., the second insulation layer pattern 190a may cover sidewalls of the first, second, and third upper conductive layer patterns 182a, 184a, and 186a). A second recess 192 may be formed beneath the second insulation layer pattern 192. In an implementation, the second insulation layer pattern 190a may have a thickness that becomes greater, e.g., increases, from a bottom portion to a top portion thereof. Thus, the second recess 192 may have a width that narrows from a bottom portion to a top portion thereof.

The first and second recesses 172 and 192 may form an air gap 195 between the gate structures 162a, 164a, and 166a. For example, the first and second recesses 172 and 192 may define lower and upper portions of the air gap 195, respectively. In an implementation, the upper portion 192 of the air gap 195 may have a maximum width larger than a maximum width of the lower portion 172 of the air gap 195.

The semiconductor device may include the air gap 195 (defined by the first and second insulation layer patterns 170a and 190a) between the first, second, and third gate structures 162a, 164a, and 166a. Accordingly, undesirable parasitic capacitance and interference phenomena between the gate structures 162a, 164a, and 166a may be reduced.

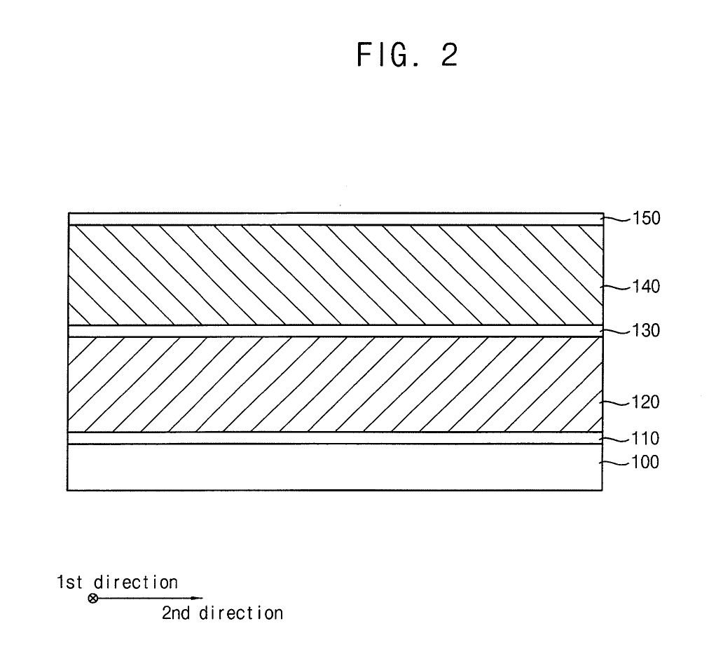

FIGS. 2 to 11 illustrate cross-sectional views of stages in a method of manufacturing a semiconductor device in accordance with an embodiment.

Referring to FIG. 2, a tunnel insulation layer 110, a floating gate layer 120, a dielectric layer 130, a control gate layer 140, and a hard mask layer 150 may be sequentially formed on a substrate 100.

The substrate 100 may be a semiconductor substrate, e.g., a silicon substrate, a germanium substrate, a silicon-germanium substrate, a silicon-on-insulator (SOI) substrate, a germanium-on-insulator (GOI) substrate, or the like. In an implementation, the substrate 100 may further include a well region (not shown) doped with p-type or n-type impurities.

The substrate 100 may be divided into a cell region (in which memory cells may be formed) and a peripheral circuit region (not shown, in which peripheral circuits may be formed).

The tunnel insulation layer 110 may be formed using an oxide such as silicon oxide, an oxynitride such as silicon oxynitride, silicon oxide doped with impurities, or a low-k dielectric material.

The floating gate layer 120 may be formed using doped polysilicon or a metal having a high work function, e.g., tungsten, titanium, cobalt, nickel, or the like.

The dielectric layer 130 may be formed using an oxide or a nitride. In an implementation, the dielectric layer 130 may have a multi-layered structure of oxide/nitride/oxide (ONO). In another implementation, the dielectric layer 130 may be formed using a metal oxide having a high dielectric constant (so that the semiconductor device may have a high capacitance and improved leakage current characteristics). The high-k metal oxide may include hafnium oxide, titanium oxide, tantalum oxide, zirconium oxide, aluminum oxide, or the like.

The control gate layer 140 may be formed using doped polysilicon, a metal, a metal nitride, a metal silicide, or the like. In an implementation, the control gate layer 140 may include doped polysilicon at least at an upper portion thereof.

The hard mask layer 150 may be formed using silicon oxide, silicon nitride, or silicon oxynitride.

In another implementation, a charge trapping layer 120, a blocking layer 130, and a gate electrode layer 140 may be sequentially formed on the tunnel insulation layer 110 (instead of the floating gate layer 120, the dielectric layer 130, and the control gate layer 140, respectively).

The charge trapping layer 120 may be formed using a nitride such as silicon nitride or a metal oxide such as hafnium oxide. The blocking layer 130 may be formed using silicon oxide or a high-k metal oxide such as hafnium oxide, titanium oxide, tantalum oxide, zirconium oxide, aluminum oxide, or the like. The gate electrode layer 140 may be formed using doped polysilicon, a metal, a metal nitride, a metal silicide, or the like. In an implementation, the gate electrode layer 140 may include doped polysilicon at an upper portion thereof.

Hereinafter, the structure including the floating gate layer 120, the dielectric layer 130, and the control gate layer 140 sequentially stacked on the tunnel insulation layer 110 is described.

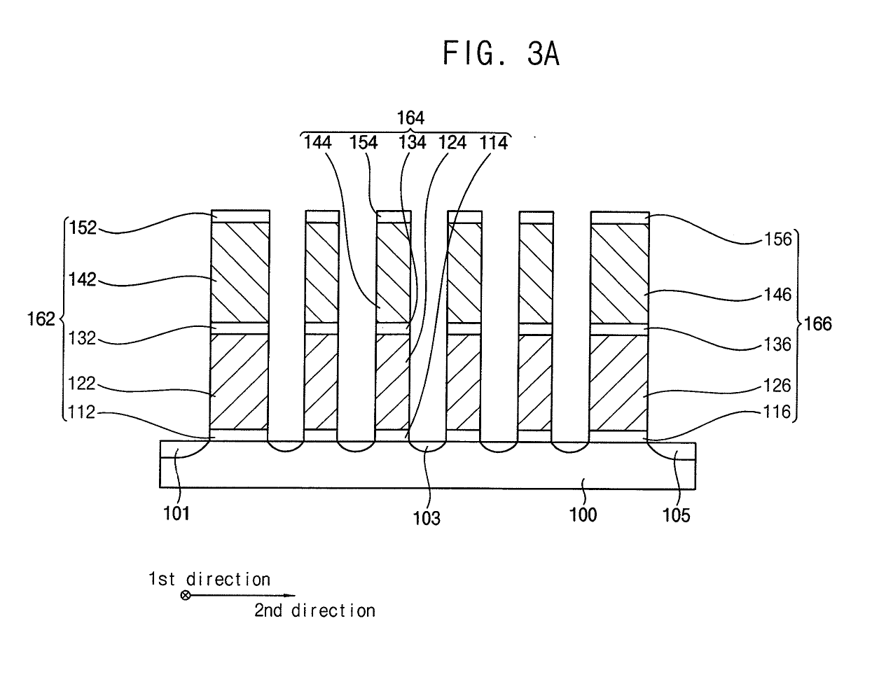

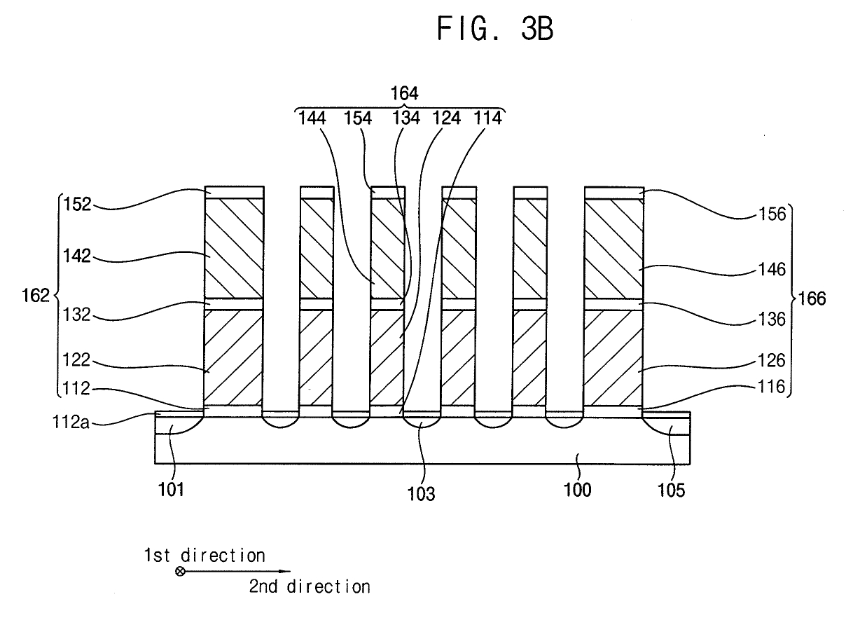

Referring to FIG. 3A, the hard mask layer 150, the control gate layer 140, the dielectric layer 130, the floating gate layer 120, and the tunnel insulation layer 110 may be sequentially etched by a photolithography process to form first, second, and third preliminary gate structures 162, 164, and 166 on the substrate 100. The first, second, and third preliminary gate structures 162, 164, and 166 may respectively include first, second, and third tunnel insulation layer patterns 112, 114, and 116, first, second, and third floating gates 122, 124, and 126, first, second, and third dielectric layer patterns 132, 134, and 136, first, second, and third preliminary control gates 142, 144, and 146, and first, second, and third hard mask pattern 152, 154, and 156 sequentially stacked on the substrate 100.

In an implementation, the first, second, and third preliminary gate structures 162, 164, and 166 may be formed in the cell region. By performing subsequent processes, the first and third preliminary control gates 142 and 146 may serve as a string selection line (SSL) and a ground selection line (GSL), respectively; and the second preliminary control gate 144 may serve as a word line (W/L).

In an implementation, the tunnel insulation layer patterns 112, 114, and 116 may have an island shape, e.g., isolated from each other on the substrate 100. The floating gates 122, 124, and 126 may also have an island shape, e.g., isolated from each other. In an implementation, each of the dielectric layer patterns 132, 134, and 136, each of the preliminary control gates 142, 144, and 146, and each of the hard mask patterns 152, 154, and 156 may extend in the first direction. The dielectric layer patterns 132, 134, and 136 may be spaced apart from each other in the second direction, the preliminary control gates 142, 144, and 146 may be spaced apart from each other in the second direction, and the hard mask patterns 152, 154, and 156 may be spaced apart from each other in the second direction.

In FIG. 3A, four second preliminary gate structures 164 are illustrated, however, the number of the second preliminary gate structure 164 is not limited thereto.

In another implementation, as illustrated in FIG. 3B, the tunnel insulation layer patterns 112, 114, and 116 may not have an island shape, e.g., may not be isolated from each other, but rather may also extend in the second direction. In this case, portions of the tunnel insulation layer patterns 112, 114, and 116 (that are not covered by the floating gates 122, 124, and 126, respectively), may have a relatively small thickness. For example, the tunnel insulation layer 110 may be patterned to form a plurality of lines or bars extending in the second direction; and upper portions of the lines or bars (which are not covered by the floating gates 122, 124, and 126) may be removed to form a fourth tunnel insulation layer pattern 112a. The tunnel insulation layer 110 may not be completely removed from the substrate 100. Thus, damage to the substrate 100 during the patterning process may be reduced or prevented.

Referring back to FIG. 3A, impurities may be implanted into the substrate 100 using the preliminary gate structures 162, 164, and 166 as an ion implantation mask. Thus, first, second, and third impurity regions 101, 103, and 105 may be formed at upper portions of the substrate 100 (adjacent to the preliminary gate structures 162, 164, and 166, respectively).

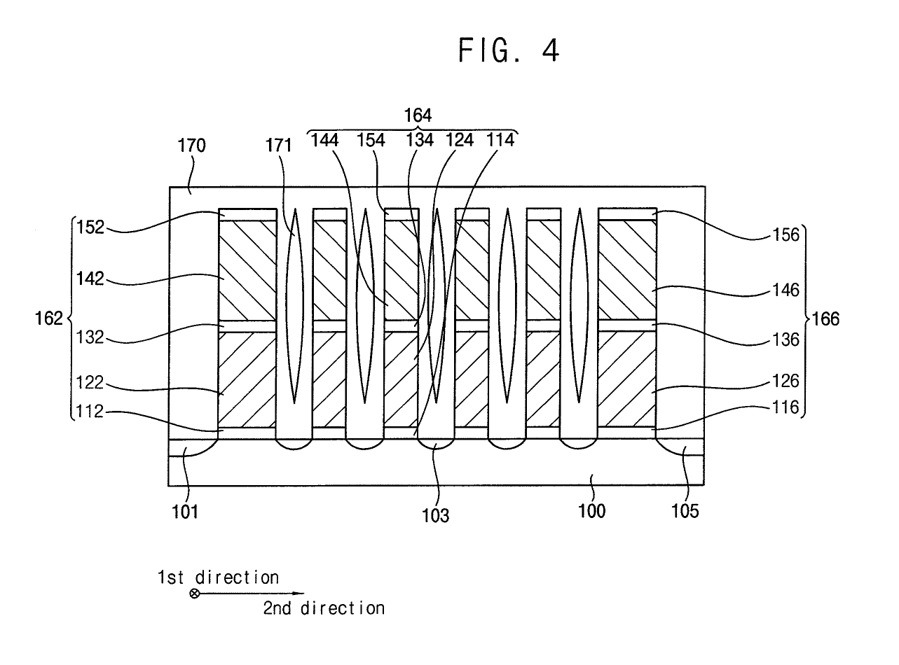

Referring to FIG. 4, a first insulation layer 170 may be formed on the substrate 100 to cover the preliminary gate structures 162, 164, and 166.

The first insulation layer 170 may be formed using silicon oxide, silicon nitride, or silicon oxynitride by a chemical vapor deposition (CVD) process, an atomic layer deposition (ALD) process, a physical vapor deposition (PVD) process, or the like. In an implementation, the first insulation layer 170 may be formed using high temperature oxide (HTO), middle temperature oxide (MTO), or atomic layer deposition (ALD) oxide. The first insulation layer 170 may be formed under a condition having low gap filling characteristics such that a void 171 may be formed between the preliminary gate structures 162, 164, and 166.

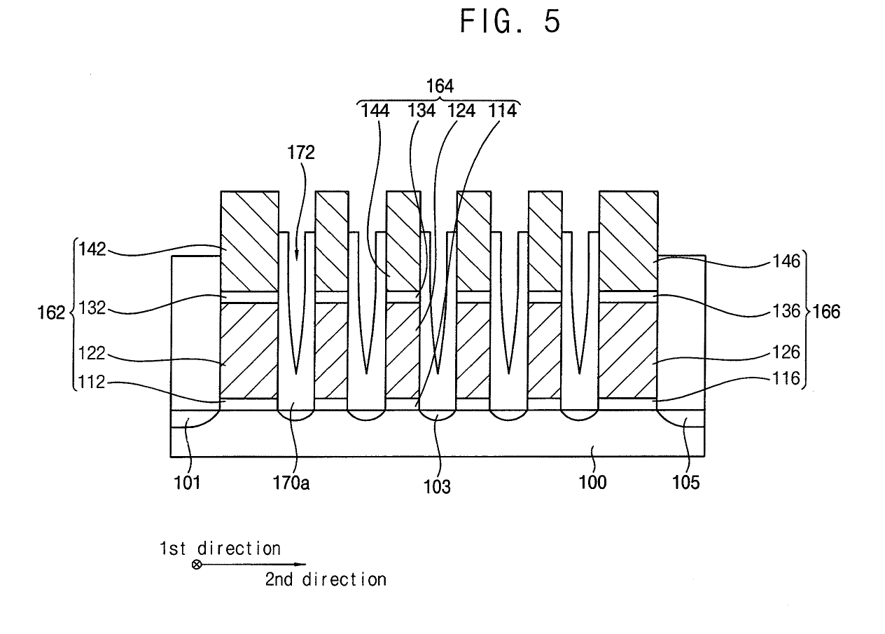

Referring to FIG. 5, an upper portion of the first insulation layer 170 may be removed to form a first insulation layer pattern 170a; and the void 171 and the preliminary control gates 142, 144, and 146 may be partially exposed. For example, the first insulation layer pattern 170a may be formed on sidewalls of the tunnel insulation layer patterns 112, 114, and 116, the floating gates 122, 124, and 126, and the dielectric layer patterns 132, 134, and 136, on lower portions of sidewalls of the preliminary control gates 142, 144, and 146, and on a top surface of the substrate 100 between the preliminary gate structures 162, 164, and 166.

The hard mask patterns 152, 154, and 156 may be removed together with the upper portion of the first insulation layer 170 to expose top surfaces of the preliminary control gates 142, 144, and 146. In an implementation, portions of the preliminary control gates 142, 144, and 146 including doped polysilicon may be exposed.

In an implementation, the upper portion of the first insulation layer 170 may be removed by a chemical mechanical polish (CMP) process and/or an etch-back process.

The void 171 may be exposed during removal of the upper portion of the first insulation layer 170 to form a first recess 172 (e.g., defined by the first insulation layer pattern 170a remaining between the first, second, and third preliminary gate structures 162, 164, and 166).

In an implementation, the first recess 172 may have a width that narrows from a top portion to a bottom portion thereof. For example, the first insulation layer pattern 170a may have a thickness that increases from a top portion to a bottom portion thereof.

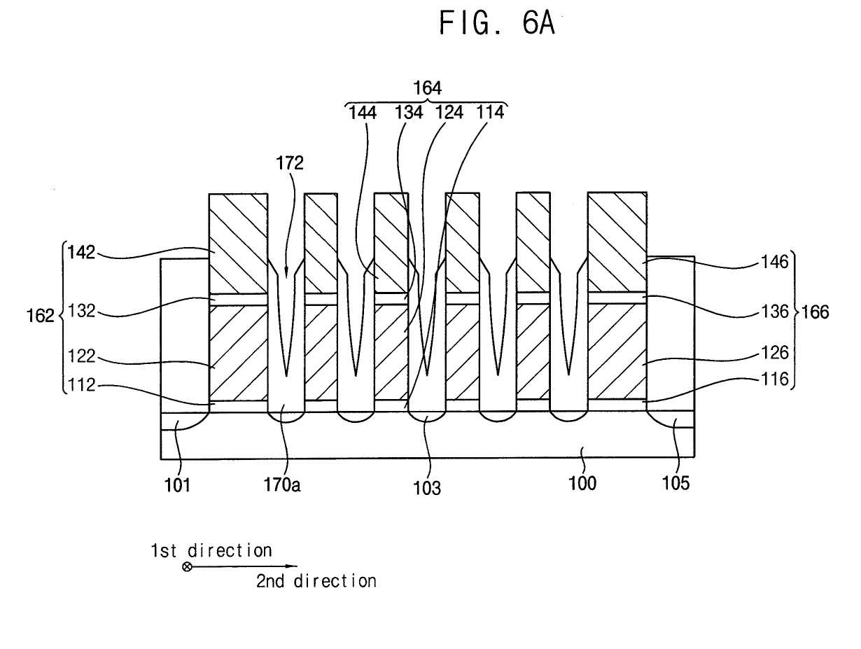

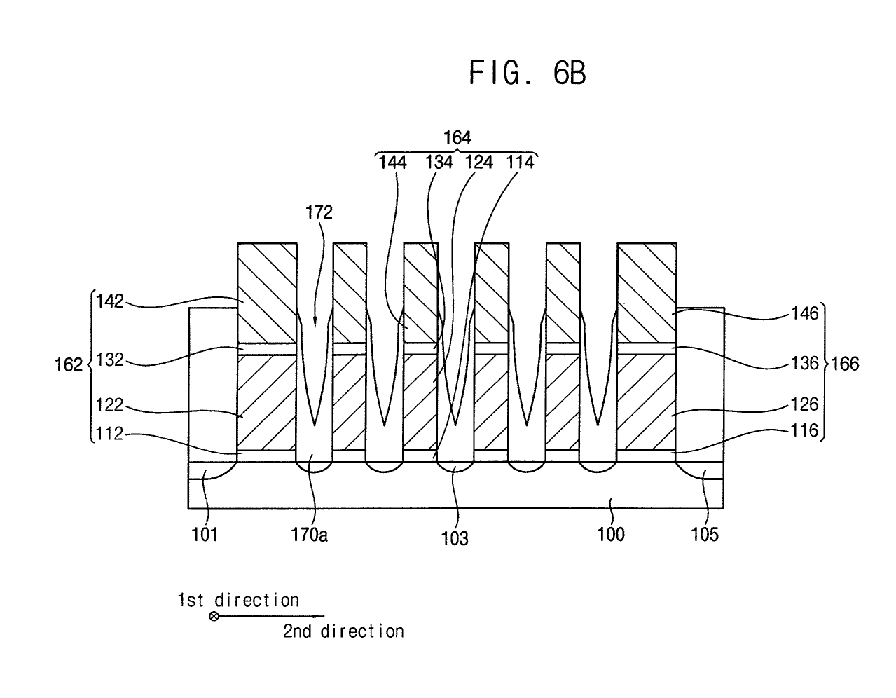

In an implementation, as illustrated in FIG. 6A, an upper portion of the first insulation layer pattern 170a (near an entrance or opening of the first recess 172) may be partially removed so that the entrance of the first recess 172 may be enlarged. In this case, the portions of the first insulation layer pattern 170a on sidewalls of the preliminary gate structures 162, 164, and 166 may not be removed.

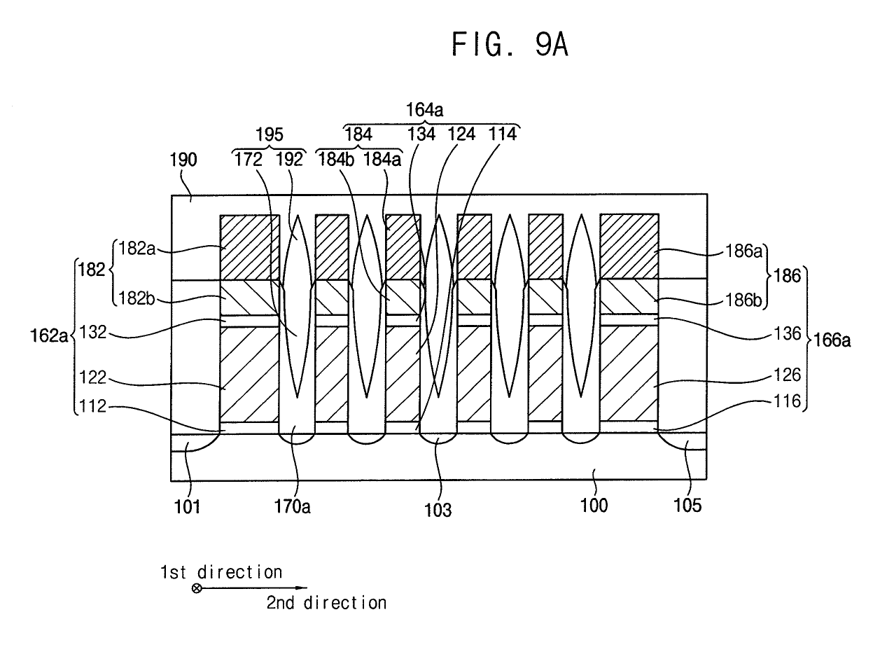

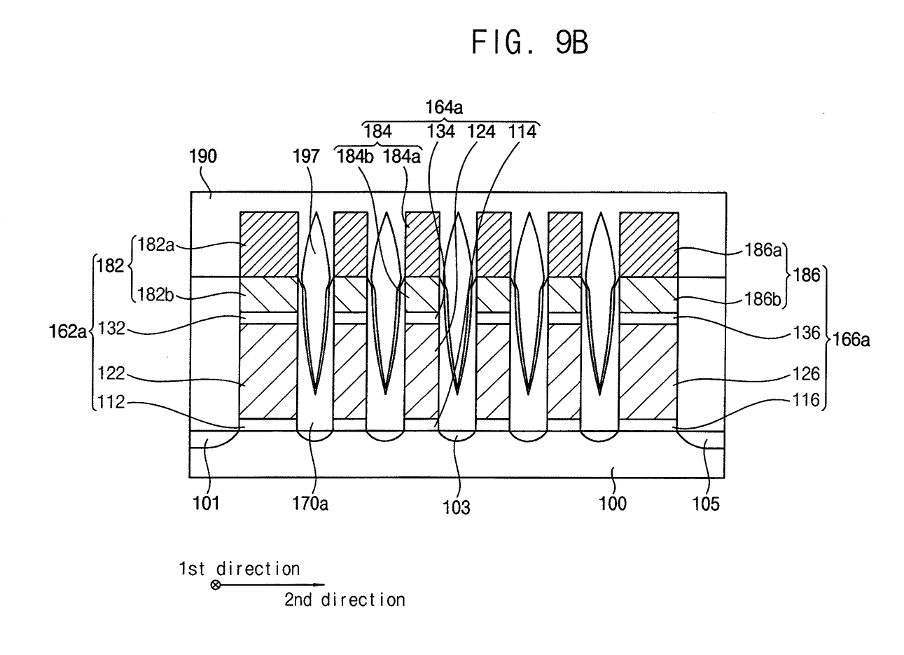

In an implementation, as illustrated in FIG. 6B, an etching process may be further performed on a sidewall of the first insulation layer pattern 170a so that the width of the first recess 172 may be increased. Accordingly, an air gap 195 (see FIG. 9A) may also have a larger width. In this case, the first recess 172 may also have a width that narrows from a top portion to a bottom portion thereof. In an implementation, the etching process may include a wet etching process using a fluoric acid (HF) solution.

In an implementation, processes for enlarging the first recess 172 described with respect to FIGS. 6A and 6B may not be essential, and thus may be omitted. However, the structure in which the first recess 172 has an enlarged width or entrance is explained hereinafter.

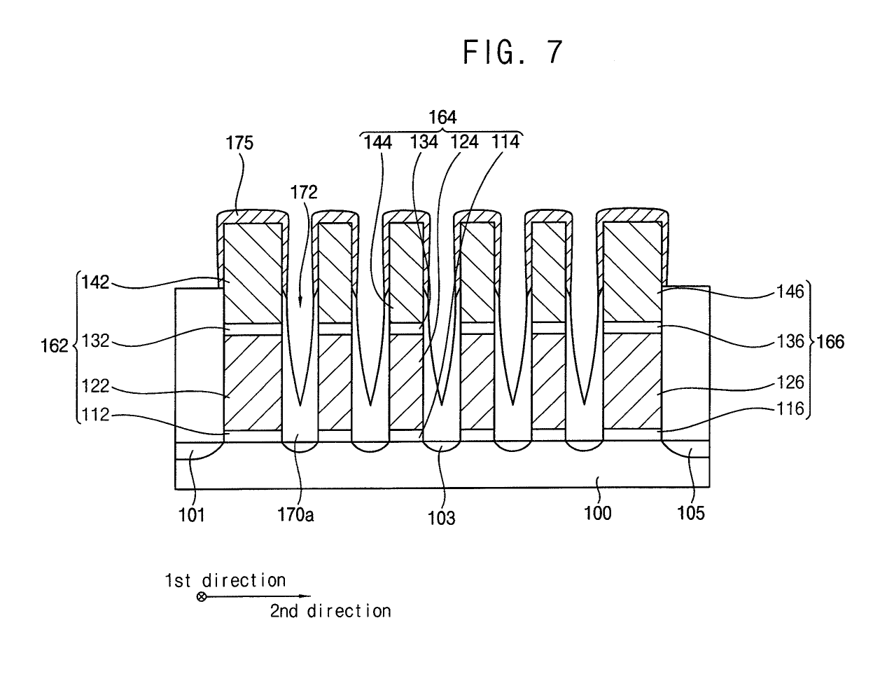

Referring to FIG. 7, a conductive layer 175 may be formed on the exposed portions of the preliminary control gates 142, 144, and 146.

In an implementation, the conductive layer 175 may be formed using a metal, e.g., cobalt, nickel, or the like, by a PVD process. The first insulation layer pattern 170a may restrict a region on which the conductive layer 175 may be formed.

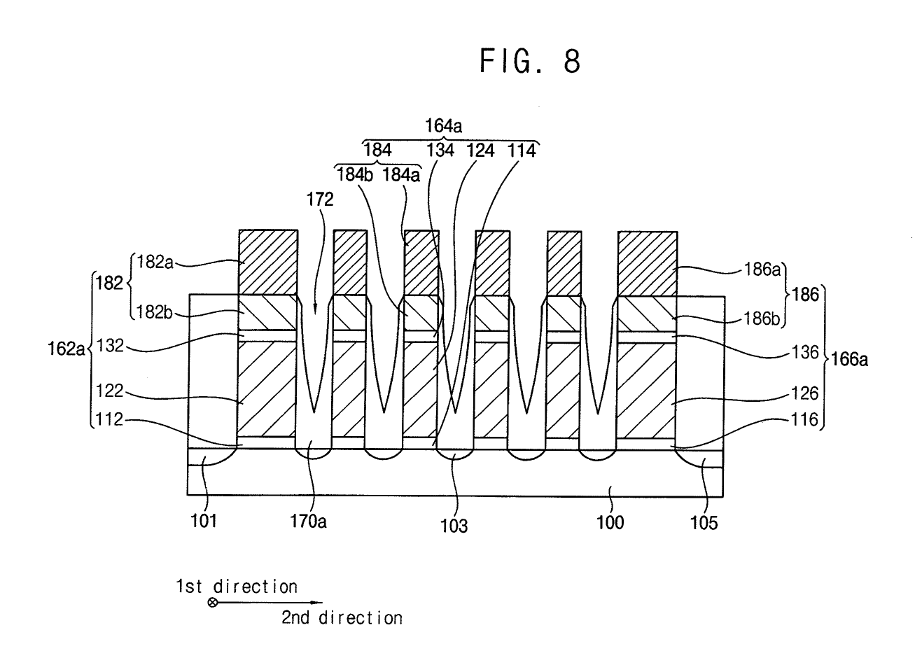

Referring to FIG. 8, portions of the preliminary control gates 142, 144, and 146 may react with the conductive layer 175 to form first, second, and third upper conductive patterns 182a, 184a, and 186a, respectively. Portions of the preliminary control gates 142, 144, and 146 that are not reacted with the conductive layer 175 may be defined as first, second, and third lower conductive patterns 182b, 184b, and 186b, respectively. The first, second, and third upper conductive patterns 182a, 184a, and 186a (together with the first, second, and third lower conductive patterns 182b, 184b, and 186b) may define first, second, and third control gates 182, 184, and 186, respectively.

In an implementation, portions of the preliminary control gates 142, 144, and 146 including doped polysilicon may react with the conductive layer 175 to form the upper conductive patterns 182a, 184a, and 186a including a metal silicide. The silicidation process may be performed by a heat treatment. For example, when the conductive layer 175 includes cobalt, a cobalt silicide layer may be formed, while a nickel silicide layer may be formed when the conductive layer 175 includes nickel.

Portions of the preliminary gate structures 162, 164, and 166 that are not covered by the first insulation layer pattern 170a may react with the conductive layer 195. Thus, the first insulation layer pattern 170a may serve as a reaction prevention pattern. Accordingly, the upper conductive patterns 182a, 184a, and 186a may have bottom surfaces substantially coplanar with or may abut a top surface of the first insulation layer pattern 170a.

By performing the above processes, first, second, and third gate structures 162a, 164a, and 166a may be formed on the substrate 100. The first, second, and third gate structures 162a, 164a, and 166a may respectively include the first, second, and third tunnel insulation layer patterns 112, 114, and 116, the first, second, and third floating gates 122, 124, and 124, the first, second, and third dielectric layer patterns 132, 134, and 136, and the first, second, and third control gates 182, 184, and 186 sequentially stacked on the substrate 100. The first, second, and third control gates 182, 184, and 186 may include the first, second, and third lower conductive patterns 182b, 184b, and 186b, and the first, second, and third upper conductive patterns 182a, 184a and 186a, respectively.

Referring to FIG. 9A, a second insulation layer 190 may be formed on the substrate 100 to cover the gate structures 162a, 164a, and 166a. The second insulation layer 190 may be formed using a material having low step coverage. Thus, the second insulation layer 190 may be formed on sidewalls and top surfaces of the upper conductive patterns 182a, 184a, and 186a (that are not covered by the first insulation layer pattern 170a). In an implementation, the second insulation layer 190 may not be formed on an inner wall of the first recess 172 (that is defined by the first insulation layer pattern 170a) and may only make contact with the top surface of the first insulation layer pattern 170a. Accordingly, a second recess 192 (in fluid communication with the first recess 172) may be formed beneath the second insulation layer 190 (between the first, second, and third gate structures 162a, 164a, and 166a).

The first and second recesses 172 and 192 may define the first air gap 195. For example, the first and second recesses 172 and 192 may define a lower portion and an upper portion of the first air gap 195, respectively.

In an implementation, the first recess 172 may have a width that narrows from a top portion to a bottom portion thereof; and the second recess 192 may have a width that narrows from a bottom portion to a top portion thereof. In an implementation, the upper portion of the first air gap 195 may have a maximum width larger than a maximum width of the lower portion of the first air gap 195. The first air gap 195 may extend in the first direction.

The second insulation layer 190 may be formed using an oxide such as plasma enhanced oxide (PEOX), MTO, tetra ethyl ortho silicate (TEOS), or the like, by a CVD process, a plasma enhanced chemical vapor deposition (PECVD) process, a low pressure chemical vapor deposition (LPCVD) process, or the like. The second insulation layer 190 may be formed under a condition having poor step coverage so that the first air gap 195 may be formed in a space defined by a lower surface of the second insulation layer 190 and an upper surface of the first insulation layer pattern 170a.

In another implementation, referring to FIG. 9B, the second air gap 197 (that is defined only by the second insulation layer 190) may be formed. In this case, the second insulation layer 190 may be formed not only on the sidewalls and top surfaces of the upper conductive patterns 182a, 184a, and 186a not covered by the first insulation layer pattern 170a, but also on an inner wall of the first recess 172. For example, the second insulation layer 190 may have a thin thickness along the upper surface of the first insulation layer pattern 170a and may cover the exposed portions of the gate structures 162a, 164a, and 166a. The second air gap 197 may have a shape substantially similar to that of the first air gap 195.

Hereinafter, only the case in which the first air gap 195 is formed is described.

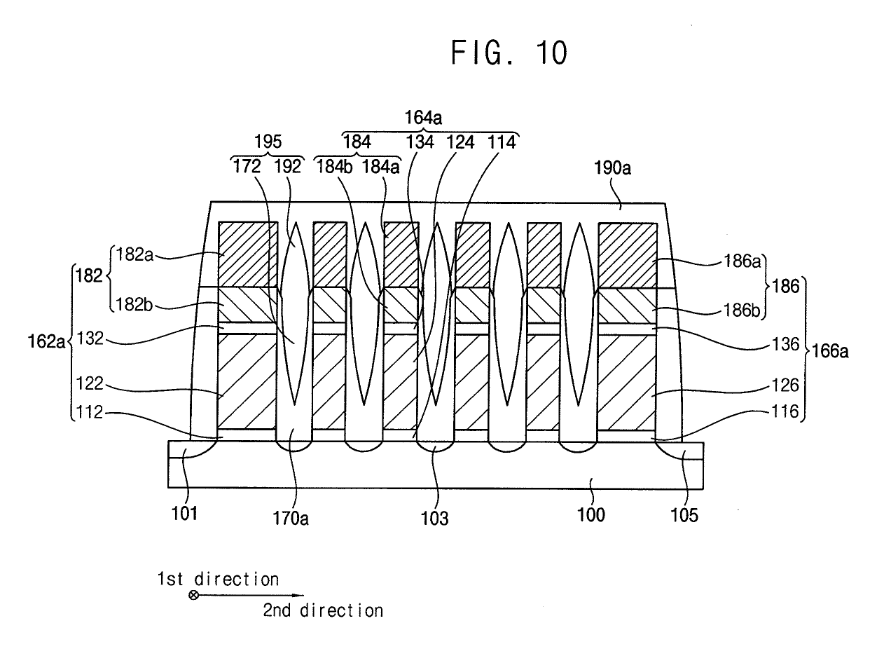

Referring to FIG. 10, the second insulation layer 190 and the first insulation layer pattern 170a may be partially removed by a photolithography process to expose the first and second impurity regions 101 and 105. Accordingly, the second insulation layer pattern 190a may be formed on top surfaces and portions of the sidewalls of the first, second, and third gate structures 162a, 164a, and 166a, and on the top surface of the first insulation layer pattern 190a.

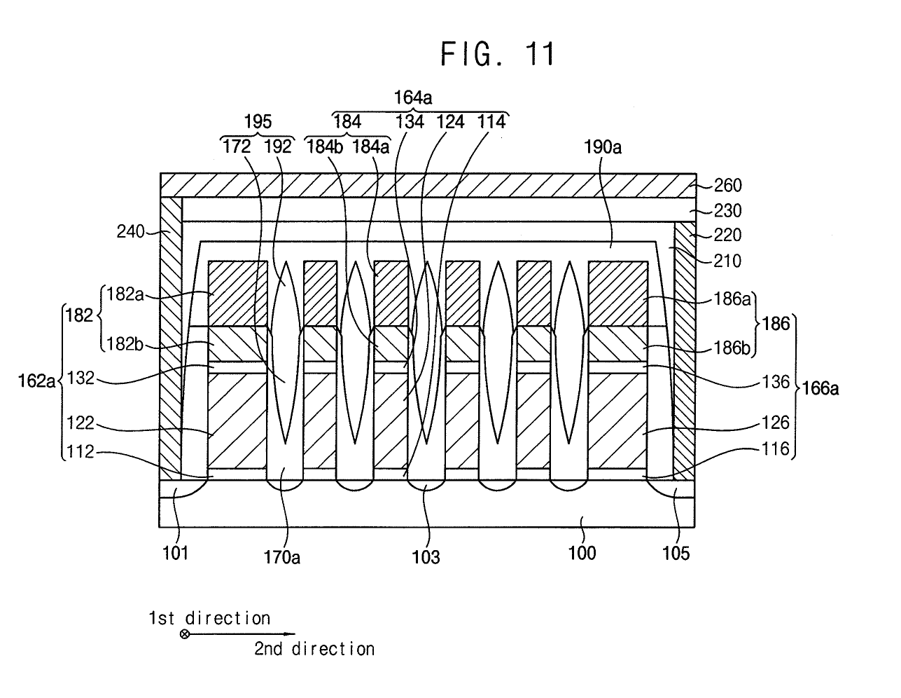

Referring to FIG. 11, a first insulating interlayer 210 may be formed on the substrate 100 to cover the first and second insulation layer patterns 170a and 190a. The first insulating interlayer 210 may be formed using an oxide such as borophosphosilicate glass (BPSG), undoped silicate glass (USG), spin on glass (SOG), or the like.

A common source line (CSL) 220 may be formed on the third impurity region 105 through the first insulating interlayer 210. The CSL 220 may be formed using doped polysilicon, a metal, or a metal silicide.

A second insulating interlayer 230 may be formed on the first insulating interlayer 210 and the CSL 220. The second insulating interlayer 230 may be formed using an oxide such as BPSG, USG, SOG, or the like.

A bit line contact 240 may be formed on the first impurity region 101 through the first and second insulating interlayers 210 and 230. The bit line contact 240 may be formed using a metal, doped polysilicon, or the like.

A bit line 260 may be formed on the second insulating interlayer 230 to be electrically connected to the bit line contact 240. The bit line 260 may extend in the second direction. The bit line 260 may be formed using a metal, doped polysilicon, or the like.

By the above processes, the semiconductor device in accordance with an embodiment may be manufactured. In FIGS. 1 to 11, a NAND flash memory device is illustrated, however, the embodiments may be also applied to other types of semiconductor devices, e.g., a NOR flash memory device, a DRAM device, or the like.

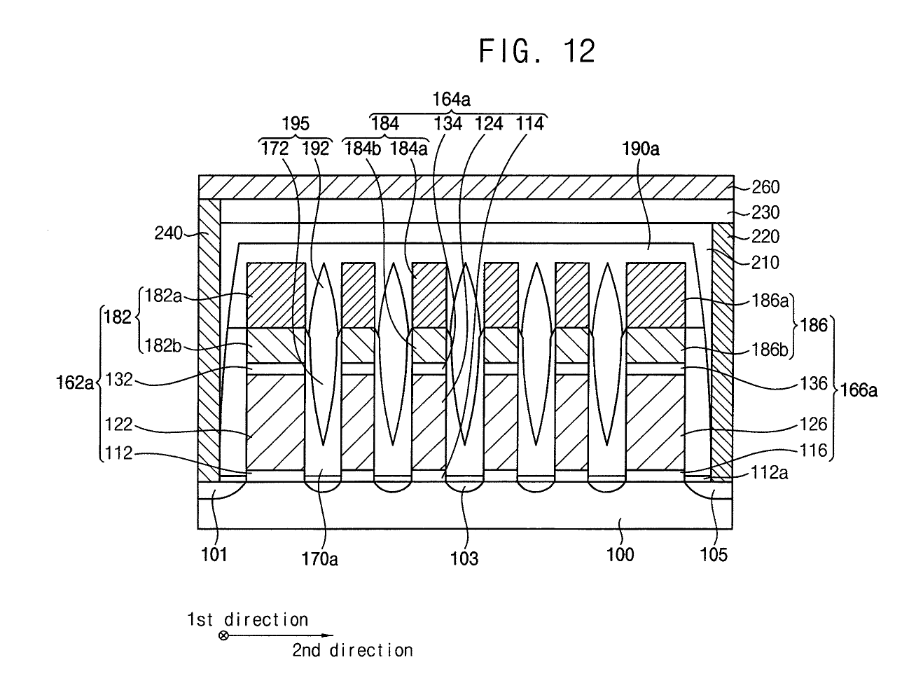

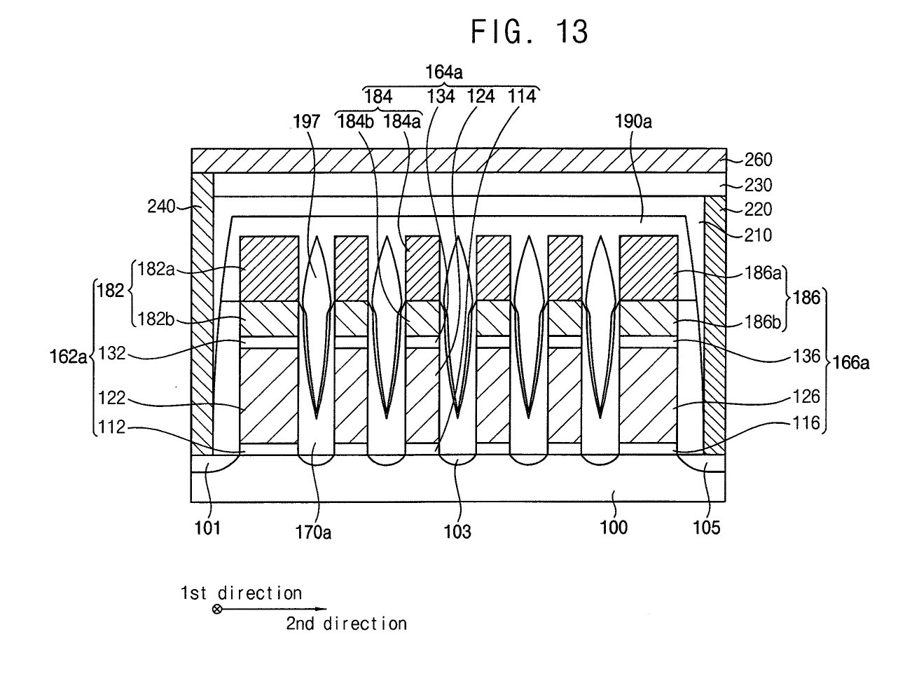

FIGS. 12 and 13 illustrate cross-sectional views showing semiconductor devices in accordance with another embodiment. The semiconductor devices in FIGS. 12 and 13 are substantially the same as that illustrated in FIG. 11 except for some elements, and thus only the differences therebetween are explained hereinafter.

The semiconductor device of FIG. 12 may further include the fourth tunnel insulation layer pattern 112a on portions of the substrate 100 between the first, second, and third gate structures 162a, 164a, and 166a. Thus, the first insulation layer pattern 170a may be formed on the sidewalls of the first, second, and third gate structures 162a, 164a, and 166a, and on the fourth tunnel insulation layer pattern 112a. The fourth tunnel insulation layer pattern 112a may have a thickness smaller than that of the first, second, and third tunnel insulation layer patterns 112, 114, and 116.

The semiconductor device of FIG. 13 may include the second air gap 197 that is defined only by the second insulation layer pattern 190a. For example, the second insulation layer pattern 190a may cover the top surfaces and the portions of the sidewalls of the first, second, and third gate structures 162a, 164a, and 166a, and may be formed thinly on the inner wall of the first recess 172 that is defined by the first insulation layer pattern 170a. The second air gap 197 may have a shape substantially similar to that of the first air gap.

By way of summation and review, as semiconductor devices have become more highly integrated, a parasitic capacitance or an interference phenomenon may occur between gate structures. For example, an oxide layer filling spaces between the gate structures may have a high dielectric constant, so that the parasitic capacitance may become large. Thus, reliability of semiconductor devices may be reduced.

The embodiments provide a method of forming an air gap between the gate structures. The embodiments also provide semiconductor devices having air gaps.

According to the embodiments, a first insulation layer pattern may be formed on portions of sidewalls of gate structures spaced apart from each other and on portions of a substrate between the gate structures. A conductive layer may be formed on portions of the gate structures that are not covered by the first insulation layer pattern. The gate structures may react with the conductive layer using the first insulation layer pattern as a reaction prevention layer to form a metal silicide layer so that control gates having low resistance may be formed. Additionally, a second insulation layer may be formed on the portions of the gate structures that are not covered by the first insulation layer pattern to form an air gap between the gate structures. Therefore, the semiconductor device having a reduced parasitic capacitance and interference between word lines may be manufactured.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a semiconductor device, the method comprising:
forming a plurality of gate structures spaced apart from each other on a substrate;
forming a first insulation layer covering the gate structures, the first insulation layer including a void between the gate structures;
removing an upper portion of the first insulation layer to form a first insulation layer pattern on sidewalls of lower portions of the gate structures and on the substrate between the gate structures, the first insulation layer pattern including a first recess thereon;
forming a conductive layer on upper portions of the gate structures exposed by the first insulation layer pattern;
reacting the conductive layer with the gate structures; and
forming a second insulation layer on the upper portions of the gate structures, the second insulation layer including a second recess therebeneath in fluid communication with the first recess.

2. The method as claimed in claim 1, wherein the first and second recesses form an air gap, the first and second recesses defining lower and upper portions of the air gap, respectively.

3. The method as claimed in claim 1, wherein the first recess has a width that narrows from a top portion to a bottom portion thereof.

4. The method as claimed in claim 1, wherein the second recess has a width that narrows from a bottom portion to a top portion thereof.

5. The method as claimed in claim 1, wherein the second recess has a maximum width larger than a maximum width of the first recess.

6. The method as claimed in claim 1, wherein:
each of the gate structures includes a tunnel insulation layer pattern, a floating gate, a dielectric layer pattern, and a control gate sequentially stacked on the substrate, the control gate including doped polysilicon, and
the first insulation layer pattern is formed on the substrate between the gate structures.

7. The method as claimed in claim 1, wherein:
the conductive layer is formed using a metal, and
reacting the conductive layer with the gate structures includes forming a metal silicide layer.

8. The method as claimed in claim 1, wherein the first insulation layer is formed using at least one selected from the group of middle temperature oxide (MTO), high temperature oxide (HTO), and atomic layer deposition (ALD) oxide.

9. The method as claimed in claim 1, wherein the second insulation layer is formed using at least one selected from the group of plasma enhanced oxide (PEOX), MTO, and tetra ethyl ortho silicate (TEOS).

10. The method as claimed in claim 1, further comprising at least partially etching sidewalls of the first recess to enlarge the first recess after forming the first insulation layer pattern.

11. The method as claimed in claim 1, wherein:
each of the gate structures includes a tunnel insulation layer pattern, a charge trapping layer pattern, a blocking layer pattern, and a gate electrode sequentially stacked on the substrate, the gate electrode including doped polysilicon, and
the first insulation layer pattern is formed on the substrate between the gate structures.

12. A semiconductor device, comprising:
a plurality of gate structures spaced apart from each other on a substrate;
a first insulation layer pattern on sidewalls of lower portions of the gate structures and on a top surface of the substrate between the gate structures, the first insulation layer pattern including a first recess thereon and having a thickness that increases from a top portion to a bottom portion thereof; and
a second insulation layer pattern covering upper portions of the gate structures that are not covered by the first insulation layer pattern, the second insulation layer pattern including a second recess therebeneath in fluid communication with the first recess and having a thickness that increases from a bottom portion to a top portion thereof.

13. The semiconductor device as claimed in claim 12, wherein the first and second recesses form an air gap, the first and second recesses defining lower and upper portions of the air gap, respectively

14. The semiconductor device as claimed in claim 12, wherein the second recess has a maximum width larger than a maximum width of the first recess.

15. The semiconductor device as claimed in claim 12, wherein:
each of the gate structures includes a tunnel insulation layer pattern, a floating gate, a dielectric layer pattern, and a control gate sequentially stacked on the substrate, the control gate including doped polysilicon, and
the first insulation layer pattern is formed on the substrate between the gate structures.

16. A method of manufacturing a semiconductor device, the method comprising:
providing a substrate;
forming a plurality of gate structures spaced apart from each other on the substrate such that each of the plurality of gate structures includes a tunnel insulation layer pattern, one of a floating gate and charge trapping layer pattern, one of a dielectric layer pattern and a blocking layer pattern, and one of a control gate and a gate electrode sequentially stacked on the substrate;
forming a first insulation layer on the plurality of gate structures such that the first insulation layer includes a void between adjacent gate structures;
removing an upper portion of the first insulation layer to form a first insulation layer pattern on sidewalls of lower portions of the gate structures and on the substrate between the gate structures such that the first insulation layer pattern includes a first recess therein;
forming a conductive layer on upper portions of each control gate or gate electrode;
reacting the conductive layer with the upper portions of each control gate or gate electrode to form an upper conductive pattern; and
forming a second insulation layer on the gate structures such that the second insulation layer includes a second recess therein and an air gap is formed between adjacent gate structures.

17. The method as claimed in claim 16, wherein an upper portion of the air gap is defined by the second recess and a lower portion of the air gap is defined by the first recess.

18. The method as claimed in claim 16, wherein the second insulation layer covers the first recess such that the air gap is defined by the second recess.

19. The method as claimed in claim 16, wherein reacting the conductive layer with the upper portions of each control gate or gate electrode includes performing a heat treatment.
